(19) United States
(12) Patent Application Publication
(10) Pub. No.: US 2005/0056938 A1
(43) Pub. Date: Mar. 17, 2005

(54) Semiconductor device

(76) Inventors: Hiromi Shimazu, Kashiwa (JP); Tomio Iwasaki, Tsukuba (JP); Hiroyuki Ohta, Tsuchiura (JP)

Correspondence Address: ANTONELLI, TERRY, STOUT & KRAUS, LLP, 1300 NORTH SEVENTEENTH STREET, SUITE 1800, ARLINGTON, VA, 22209-9889, US

(21) Appl. No.: 10/901,998

(22) Filed: Jul. 30, 2004

(30) Foreign Application Priority Data
Sep. 11, 2003 (JP) 2003-319188

(51) Int. Cl. H01L 21/4763

(52) U.S. Cl. 257/758

(57) ABSTRACT

A semiconductor device has a wiring structure in which an insulating layer, a wiring layer made of Al and containing at least either Au or Ag as an additional element, and a protecting layer are sequentially laminated on a substrate, so that a peel-off does not occur at an interface between the Al film and a substratum insulative material in an Al wiring structure made of Al as a main component material.

### BACKGROUND OF THE INVENTION

The invention relates to a semiconductor device such as a semiconductor integrated circuit or the like having wirings whose main component material is made of Al.

The realization of a high speed is demanded in an integrated circuit of a semiconductor device, high integration, and fineness of wirings are being progressed. In association with them, a wiring delay becomes remarkable and application of low-resistance wirings and a film of a low dielectric constant is demanded. Therefore, an Al or Cu film is examined as a wiring material. In the case of a pure Al film, it is most excellent in terms of a small wiring resistance. However, since there is a problem of occurrence of migration, an Al alloy film containing Si or Cu is used in order to prevent the migration.

As a material of an interlayer insulating film, the application of a film of a low dielectric constant such as silicon oxyfluoride (SiOF) or the like in place of the conventional silicon oxide (for example, SiO₂) or the like is examined.

For example, as an example of a semiconductor device having an Al wiring structure, JP-A-5-343401 has been known.

However, in a laminated structure of the insulating film and the Al film, when a thermal load is applied, a high compression stress is generated in the Al film due to a thermal stress. There is a possibility that peel-off is caused at an interface between the insulating film and Al by the generated stress. It has been confirmed that, particularly, in the case of using the insulating film of a low dielectric constant as an insulating film, adhesion with the Al film deteriorates more than that in the case of the conventional SiO₂ film. Therefore, there is a risk of occurrence of peel-off at the interface between a substratum insulating film and the Al film.

### BRIEF SUMMARY OF THE INVENTION

It is, therefore, an object of the invention to provide a semiconductor device which operates stably without causing peel-off in an Al wiring structure in which Al is used as a main component material.

Outlines of typical aspects among the inventions disclosed here will be briefly explained as follows.

The above object is accomplished by setting a wiring structure in a semiconductor device to a laminated structure in which an insulating layer, a wiring layer composed of Al and containing at least either Au or Ag as an additional element, and an insulating layer are sequentially laminated in order of a lower layer.

In the above device, preferably, Au or Ag as an additional element is segregated to a grain boundary in the Al film.

In the above device, preferably, a ratio of the Au element or Ag element to Al is equal to 0.02 to 2 at % (atomic percentage).

According to the invention, a semiconductor device of high reliability which can reduce a compression stress of an Al film, can prevent peel-off at an interface between the Al film and a substratum insulating film, and operates stably is provided.

According to the invention, since at least either the Au element or the Ag element is contained in the Al film, the compression stress occurring in the Al film can be reduced. Therefore, even when a heat treatment of about 200° C. or higher is executed in a step after the Al film was formed, the compression stress occurring in the Al film does not reach a critical stress of the occurrence of the peel-off. The peel-off at the interface between the substratum insulative material and the Al film can be prevented. There is also such an effect that the Au element and the Ag element can suppress acceleration of grain boundary diffusion of Al atoms in the Al film and a defect due to the migration can be also prevented. Therefore, a semiconductor device of the high reliability in which a defect such as peel-off or the like does not occur and the number of manufacturing steps is not increased and which operates stably is provided.

Other objects, features and advantages of the invention will become apparent from the following description of the embodiments of the invention taken in conjunction with the accompanying drawings.

### BRIEF DESCRIPTION OF THE SEVERAL VIEWS OF THE DRAWING

FIG. 1 is a schematic cross sectional view showing a main portion of a semiconductor device according to the embodiment 1 of the invention;

FIG. 2 is a graph schematically showing relations among a stress in a film which occurs in an Al film containing Au or Ag as an additional element, a stress in a film which occurs in a conventional Al film, and a heat treatment temperature;

FIG. 3 is a diagram showing an acceleration/suppression effect of an Al atom grain boundary diffusion coefficient in the Al film due to the containment of the additional element;

FIG. 4 is a schematic cross sectional view showing a wiring structure according to the embodiment 2 of the invention;

FIG. 5 is a schematic cross sectional view showing a wiring structure according to the embodiment 3 of the invention;

FIG. 6 is a schematic cross sectional view showing a wiring structure according to the embodiment 4 of the invention;

FIG. 7 is a schematic cross sectional view showing a wiring structure according to the embodiment 5 of the invention;

FIG. 8 is a schematic cross sectional view showing a wiring structure according to the embodiment 6 of the invention;

FIG. 9 is a schematic cross sectional view showing a wiring structure according to the embodiment 7 of the invention;

FIG. 10 is a schematic cross sectional view showing a main portion of a semiconductor device according to the embodiment 8 of the invention;

FIG. 11 is a schematic cross sectional view showing a main portion of a semiconductor device according to the embodiment 9 of the invention; and

FIG. 12 is a schematic cross sectional view showing a main portion of a semiconductor device according to the embodiment 10 of the invention.

### DETAILED DESCRIPTION OF THE INVENTION

Embodiments of the invention will now be described hereinbelow with reference to the drawings.

### EMBODIMENT 1

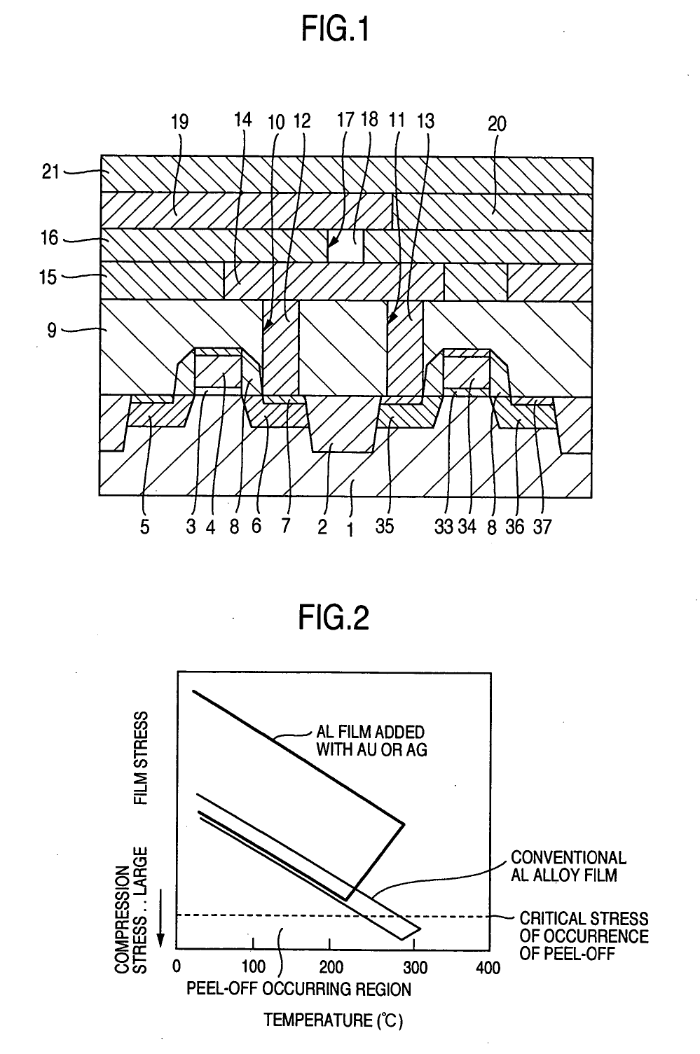

FIG. 1 is a schematic cross sectional view showing a main portion of a semiconductor device according to the embodiment 1.

As shown in FIG. 1, the semiconductor device of the embodiment 1 is constructed by using a p-type silicon substrate 1, as a main component, made of, for example, monocrystalline silicon as a semiconductor substrate. A plurality of element forming regions (active regions) partitioned by element separating regions 2 are formed on a principal plane (an element forming plane or a circuit forming plane) of the silicon substrate 1. For example, an MISFET (Metal Insulator Semiconductor Field Effect Transistor) is formed as a transistor element in each element forming region. In FIG. 1, the left side shows an n-channel conductivity type (n-type) MISFET and the right side shows a p-channel conductivity type (p-type) MISFET. The MISFET is a kind of insulating gate type field effect transistor. The MISFET whose gate insulating film is made of a silicon oxide film is ordinarily called an MOSFET (Metal Oxide Semiconductor Field Effect Transistor).

The element separating region 2 is constructed by, for example, an SGI (Shallow Groove Isolation) region. The SGI region is formed by forming a shallow groove on the principal plane of the silicon substrate 1 and, thereafter, selectively embedding an insulating film (for example, silicon oxide film) into the shallow groove.

The n-type and p-type MISFETs have constructions mainly comprising channel forming regions, gate insulating films 3 and 33, gate electrodes 4 and 34, source regions, and drain regions. The gate insulating films 3 and 33 are formed on the principal plane of the silicon substrate 1, respectively. The gate electrodes 4 and 34 are formed over the principal plane of the silicon substrate 1 through the gate insulating films 3 and 33, respectively. The channel forming regions are formed on a surface layer portion of the silicon substrate 1 just under the gate electrodes 4 and 34, respectively. The source region and the drain region of the n-type MISFET are constructed by a pair of n-type diffusion layers (n-type semiconductor regions) 5 and 6 formed on both sides in the channel length direction of the channel forming region so as to sandwich the channel forming region, respectively. The source region and the drain region of the p-type MISFET are constructed by a pair of p-type diffusion layers (p-type semiconductor regions) 35 and 36 formed on both sides in the channel length direction of the channel forming region so as to sandwich the channel forming region, respectively. Although not shown, a p-type well region is formed in the element forming region (the left side in FIG. 1) where the n-type MISFET has been formed and an n-type well region is formed in the element forming region (the right side in FIG. 1) where the p-type MISFET has been formed, respectively.

Silicide layers 7 and 37 as metal/semiconductor reactive layers are formed on upper surfaces of the gate electrodes 4 and 34 and upper surfaces of the diffusion layers 5, 6, 35, and 36, respectively.

Each of the gate insulating films 3 and 33 is made of, for example, a dielectric film of silicon oxide, silicon nitride, titanium oxide, zirconium oxide, hafnium oxide, tantalum pentoxide, or the like, or their laminated structure and formed by using, for example, a chemical vapor phase epitaxy method, a sputtering method, or the like. Each of the gate electrodes 4 and 34 is made of, for example, a polysilicon film, a thin metal film, a silicon germanium film, a metal silicide film, or their laminated structure and formed by using, for example, the chemical vapor phase epitaxy method, the sputtering method, or the like.

Side walls 8 made of, for example, silicon oxide, silicon nitride, or the like are formed on side walls in the gate length direction of the gate electrodes 4 and 34, respectively.

The whole upper surface of the MISFET is covered with an insulating film (interlayer insulating film) 9 formed over the principal plane of the silicon substrate 1. The insulating film 9 is made of, for example, a film of a low dielectric constant, a BPSG (Boron-doped Phospho Silicate Glass) film, an SOG (Spin On Glass) film, or a TEOS (Tetra-Ethyl-Ortho-Silicate) film, or a silicon oxide film, a silicon nitride film, or the like formed by the chemical vapor phase epitaxy method, the sputtering method, or the like.

Wirings 14 of the first layer comprising an Al (aluminum) film to which Au (gold) or Ag (silver) has been added are formed on the insulating film 9 which covers the MISFET. The diffusion layers 6 and 35 and the wirings 14 of the first layer comprising the Al film to which Au or Ag has been added are electrically connected through contact plugs 12 and 13 formed in contact holes 10 and 11, respectively. The contact holes 10 and 11 are formed in the insulating film 9, respectively.

Further, the wirings 14 of the first layer are covered with insulating films (interlayer insulating films) 15 and 16 formed on/over the insulating film 9. Each of the insulating films 15 and 16 is made of, for example, a film of a low dielectric constant, a BPSG film, an SOG film, or a TEOS film, or a silicon oxide film, a silicon nitride film, or the like formed by the chemical vapor phase epitaxy method, the sputtering method, or the like.

Wirings 19 of the second layer comprising an Al film to which Au or Ag has been added are formed on/over upper surfaces of the insulating films 15 and 16. The wirings 14 of the first layer and the wirings 19 of the second layer are electrically connected through a contact plug 18 formed in a contact hole 17.

Further, the whole surface of the wirings 19 of the second layer is covered with insulating films (interlayer insulating films) 20 and 21 formed on/over the insulating film 16. Each of the insulating films 20 and 21 is made of, for example, a film of a low dielectric constant, a BPSG film, an SOG film, or a TEOS film, or a silicon oxide film, a silicon nitride film, or the like formed by the chemical vapor phase epitaxy method or the sputtering method.

Each of the wirings 14 of the first layer and the wirings 19 of the second layer is made of an Al film containing at least either Au or Ag as an additional element. If the Al film contains at least either Au or Ag as an additional element, another element such as Si (silicon), Cu (copper), or the like can be also contained in the Al film. Although the embodiment 1 has been shown with respect to the case where each of the wirings 14 of the first layer and the wirings 19 of the second layer is made of the Al film containing at least either Au or Ag as an additional element, the invention is not limited to such an example. Either the wirings 14 or the wirings 19 can be made of the Al film containing at least either Au or Ag as an additional element.

The contact plugs 12, 13, and 18 can be made of, for example, a conductive material such as polysilicon, tungsten, or the like or can be also made of the same material as that of the wirings 14 of the first layer or the wirings 19 of the second layer.

The operation and effects of the semiconductor device according to the embodiment 1 with the above construction will now be described hereinbelow.

In the conventional pure Al film or Al alloy containing Si or Cu, a high compression stress occurs by a heat treatment step at a temperature of about 300° C. or higher after the Al film was formed. This compression stress becomes a cause of the peel-off of the Al film from the substratum material. To prevent the peel-off of the Al film, therefore, it is desirable to suppress the occurrence of the compression stress.

The inventors et al. of the present invention has found that by allowing a specific additional element to be contained in the Al film, the high compression stress occurring in the Al film can be suppressed.

FIG. 2 shows an effect of reducing the compression stress in the Al film containing Au or Ag as an additional element.

In the conventional Al alloy, the high compression stress occurs in the Al film due to the thermal stress in association with an increase in heat treatment temperature. The peel-off occurs when the compression stress reaches a critical stress of occurrence of the peel-off. In the case of the Al film containing at least either Au or Ag as an additional element, Au or Ag is precipitated to the grain boundary due to the high-temperature heat treatment of about 200° C. or higher, so that volume contraction occurs and the compression stress of the Al film is reduced. Since the compression stress does not reach the critical stress of occurrence of the peel-off, the peel-off of the Al film from the substratum material can be prevented.

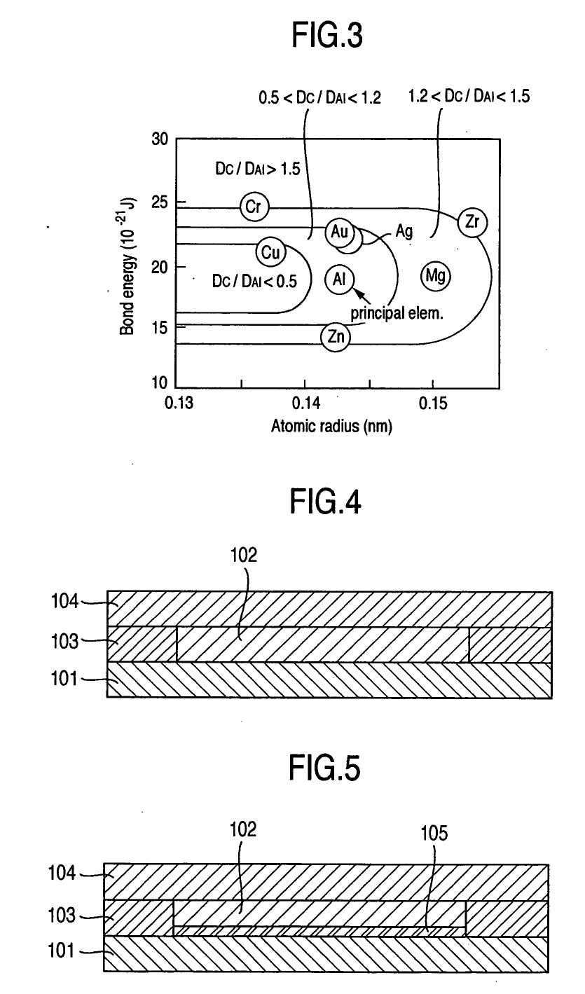

Subsequently, a grain boundary diffusion coefficient D of the Al atoms in the Al film containing Au or Ag as an additional element is calculated by a computer simulation. FIG. 3 shows an effect of the grain boundary diffusion coefficient D owing to the additional element by paying attention to an atomic radius of the additional element and a bond energy. The coefficient D is calculated by the device in which the additional element of 0.2 at % (atomic percentage) is contained in the Al film. D_{Al} denotes a grain boundary diffusion coefficient in the case where the Al film contains no additional element. It will be understood from FIG. 3 that when the additional element has an atomic radius smaller than that of the Al atoms and the bond energy of heterogeneous atoms between the Al atoms and the additional element have a value closer to a bond energy of homogeneous atoms between the Al atoms, the grain boundary diffusion coefficient D is suppressed to be smaller. When an element having a large atomic radius is added, the diffusion is extremely accelerated. However, the grain boundary diffusion coefficient D is almost equal to that in the case where the Au or Ag element is not added, that is, in the case of pure Al.

Therefore, by allowing Au or Ag to be contained as an additional element into the Al film, the sufficient compression stress reducing effect is obtained and the acceleration of the grain boundary diffusion coefficient D due to the element addition can be suppressed. Therefore, the peel-off from the substratum material can be prevented and the defect such as migration or the like can be also prevented.

It has been also confirmed by the computer simulation that if concentration of the atoms which are added to Al is set to 0.02 to 2 at %, the compression stress reducing effect and the suppressing effect of the acceleration of the grain boundary diffusion are sufficiently obtained. In a region where the atom concentration is smaller than 0.02 at %, the compression stress reducing effect is small. In a region where the atom concentration is larger than 2 at %, although the compression stress reducing effect is large, since a break of atomic arrangement increases, the grain boundary diffusion coefficient D is accelerated.

Although it is also possible that a part of the Au atoms or Ag atoms as an additional element are distributed and exist for the purpose of reducing the compression stress and suppressing the grain boundary diffusion, the highest effect is obtained when those additional elements are segregated.

As mentioned above, as shown in the embodiment 1, if the Au element or the Ag element is contained in the Al film, the compression stress occurring in the Al film can be reduced and the peel-off at the interface between the substratum insulating film and the Al film can be prevented. Since the acceleration of the grain boundary diffusion of the Al atoms in the Al film due to the addition of the element is prevented, such an effect that the defect due to the migration or the like is prevented is also obtained. Therefore, the semiconductor device which operates stably without defective conduction can be manufactured.

In the case where the Au element is added into the Al film, since Au having high oxidation resistance is pricipitated into the grain boundary, an effect of improvement of the oxidation resistance of the Al film is also obtained.

When the Ag element is added into the Al film, an effect of reducing the compression stress which is larger than that in the case where the Au element is added is obtained.

If at least one of the insulating films 9, 15, 16, 20, and 21 adjacent to the wirings 14 of the first layer or the wirings 19 of the second layer is the insulating film of a low dielectric constant such as SiOC (silicon oxycarbide), SiOF (silicon oxyfluoride), SiON (silicon oxynitride), or the like, particularly, since adhesion with the Al wirings deteriorates, there is a problem of the occurrence of peel-off at a lower stress. Therefore, when at least one of the insulating films adjacent to the wirings 14 of the first layer or the wirings 19 of the second layer is the insulating film of a low dielectric constant such as SiOC, SiOF, SiON, or the like, it is particularly important that a material of the wirings is composed of the Al film containing the Au element or the Ag element.

Although the embodiment 1 has been shown with respect to the case where the silicide layers are formed to all of the gate electrodes 4 and 34 and the diffusion layers 5, 6, 35, and 36, the invention can be also applied to a semiconductor device in which the silicide layers are formed to either the gate electrodes or the diffusion layers. The diffusion layers 5, 6, 35, and 36 can also have an LDD (Lightly Doped Drain Structure) structure. Similar effects are also obtained in those cases.

The semiconductor device of the embodiment 1 is not limited to the above example and the number of wiring layers is not limited to 2, either. The semiconductor device can be also used for a DRAM (Dynamic Random Access Memory), an SRAM (Static Random Access Memory), an EEPROM (Electrically Erasable Programmable Read Only Memory), a microcomputer, or the like.

A principal cross sectional structure of the wiring structures according to the invention and its modifications will now be described with reference to FIGS. 4 to 9.

### EMBODIMENT 2

The embodiment 2 of the invention is shown in FIG. 4. FIG. 4 shows a wiring structure similar to that in the embodiment 1 shown in FIG. 1.

In the embodiment 2, the device has a structure in which an Al film 102 to which Au or Ag has been added is formed on an insulative material 101 and the whole surface of the Al film 102 to which Au or Ag has been added is covered with insulative materials 103 and 104. Thus, effects similar to those in the embodiment 1 mentioned above are obtained. By forming the wirings as a single layer of the Al film to which Au or Ag has been added, a semiconductor device of excellent manufacturing costs can be obtained without increasing the number of manufacturing steps.

Although the insulative material 101 is not limited to that shown here, it is made of, for example, a glass material such as BPSG, SOG, or the like in which SiO₂ is used as a main component material, or a TEOS film, or silicon oxide, silicon nitride, or the like made by the chemical vapor phase epitaxy method or the sputtering method.

### EMBODIMENT 3

The embodiment 3 of the invention is shown in FIG. 5. FIG. 5 shows a modification of the wiring structure according to the invention. Component elements which are common to those in the embodiment 2 mentioned above are designated by the same reference numerals.

In the embodiment 3, a protecting film 105 is formed in a lower layer of the Al film 102 to which Au or Ag has been added. Another structure is similar to that in the embodiment 2 and effects similar to those in the embodiment 2 mentioned above are obtained. By providing the protecting film 105, such an effect of preventing the Al atoms from being diffused into the substrate or the like in the high-temperature heat treatment step is also obtained. By forming the protecting film 105 only to the lower layer of the Al film 102, there is such an advantage that the number of manufacturing steps is smaller and the manufacturing costs can be reduced more than those in the case where the protecting films are formed to the upper and lower layers of the Al film 102.

By forming the protecting film 105 by, for example, Ti (titanium), TiN (titanium nitride), Cr (chromium), Mo (molybdenum), W (tungsten), or their alloy, such an effect that the adhesion of the substratum insulative material and the Al wirings is improved is also obtained. Further, such an effect that the grain boundary diffusion D of Al is suppressed is also obtained. Thus, the semiconductor device of the high reliability in which the peel-off or the defect due to the migration does not occur in the Al wiring structure is obtained.

By forming the protecting film 105 by aluminum oxide, the adhesion between the insulative material 101 and the Al film 102 to which Au or Ag has been added is improved and such an effect that the diffusion of Al into the substratum is prevented is also obtained. Thus, the semiconductor device of the high reliability in which the peel-off or a defect due to the migration does not occur in the Al wiring structure is obtained.

### EMBODIMENT 4

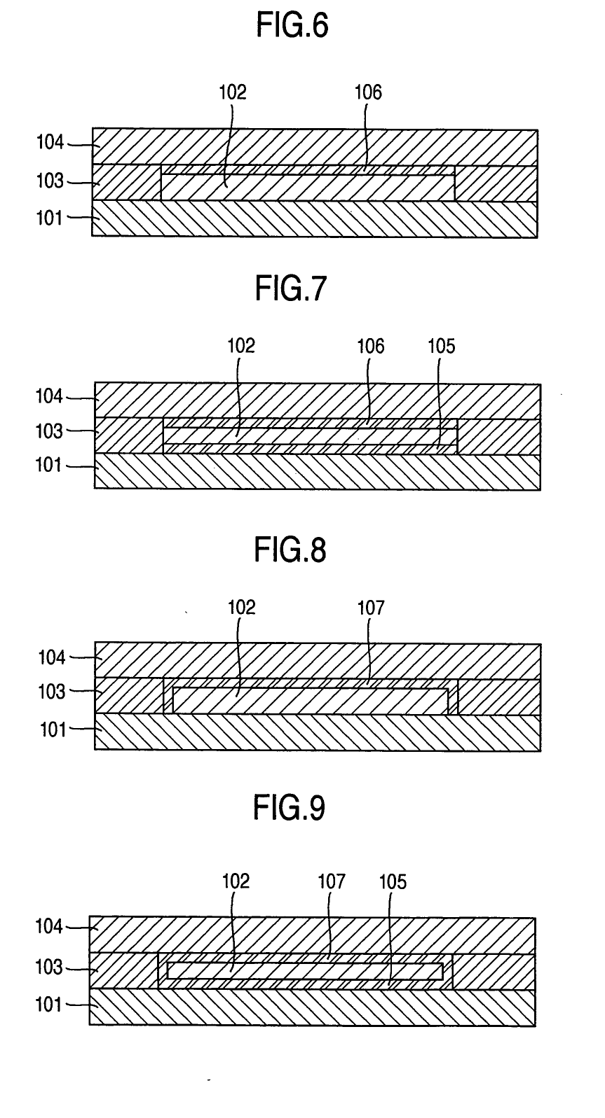

The embodiment 4 of the invention is shown in FIG. 6. FIG. 6 shows a modification of the wiring structure according to the invention. Component elements which are common to those in the embodiment 2 mentioned above are designated by the same reference numerals.

In the embodiment 4, a protecting film 106 is formed on an upper layer of the Al film 102 to which Au or Ag has been added. Another structure is similar to that in the embodiment 2 and effects similar to those in the embodiments 2 and 3 mentioned above are obtained. By forming the protecting film only onto the upper layer, there is such an advantage that the number of manufacturing steps is smaller and the manufacturing costs can be reduced more than those in the case where the protecting films are formed to the upper and lower layers.

By forming the protecting film 106 by, for example, Ti, TiN, Cr, Mo, W, or their alloy, such an effect that the adhesion between the insulative material 104 of the upper layer and the Al film 102 is improved is also obtained. Such an effect that the grain boundary diffusion D of Al is suppressed is also obtained. Thus, the semiconductor device of the high reliability in which the peel-off or a defect due to the migration does not occur in the Al wiring structure is obtained.

By forming the protecting film 106 by aluminum oxide, the adhesion between the insulative material 104 and the Al film 102 to which Au or Ag has been added is improved and such an effect that the diffusion of Al is prevented is also obtained. Thus, the semiconductor device of the high reliability in which the peel-off or a defect due to the migration does not occur in the Al wiring structure is obtained. There is also such an advantage that since the semiconductor device can be easily formed owing to the oxidation of Al, an increase in number of manufacturing steps is small.

### EMBODIMENT 5

The embodiment 5 of the invention is shown in FIG. 7. FIG. 7 shows a modification of the wiring structure according to the invention. Component elements which are common to those in the embodiment 2 mentioned above are designated by the same reference numerals.

In the embodiment 5, the protecting films 105 and 106 are formed on the upper and lower layers of the Al film 102 to which Au or Ag has been added. Another structure is similar to that in the embodiment 2 and effects similar to those in the embodiment 2 mentioned above are obtained. By providing the protecting films onto the upper and lower layers, both effects shown in the embodiments 3 and 4 mentioned above are obtained. The semiconductor device of the higher reliability is obtained.

### EMBODIMENT 6

The embodiment 6 of the invention is shown in FIG. 8. FIG. 8 shows a modification of the wiring structure according to the invention. Component elements which are common to those in the embodiment 2 mentioned above are designated by the same reference numerals.

In the embodiment 6, protecting films 107 are formed on the upper layer and the side surface of the Al film 102 to which Au or Ag has been added. Another structure is similar to that in the embodiment 2 and effects similar to those in the embodiments 2 and 3 mentioned above are obtained. Further, effects such as prevention of the diffusion of Al in the lateral direction, improvement of the adhesion with the insulative material 103, and the like are also obtained. By forming the protecting films onto the upper layer and the side surface in a lump, there is such an advantage that the number of manufacturing steps is smaller and the manufacturing costs can be reduced more than those in the case where the protecting films are formed to the upper and lower layers. A diffusion barrier effect and such an effect that the grain boundary diffusion D of Al is suppressed are higher than those in the case where the protecting film is formed only to the upper layer.

### EMBODIMENT 7

The embodiment 7 of the invention is shown in FIG. 9. FIG. 9 shows a modification of the wiring structure according to the invention. Component elements which are common to those in the embodiment 2 mentioned above are designated by the same reference numerals.

In the embodiment 7, the protecting films 105 and 107 are formed on the lower layer, the upper layer, and the side surface of the Al film 102 to which Au or Ag has been added. Another structure is similar to that in the embodiment 2 and effects similar to those in the embodiments 2 and 3 mentioned above are obtained. By forming the protecting films onto the whole peripheral surface of the Al film 102 to which Au or Ag has been added, the diffusion barrier effect and the suppressing effect of the grain boundary diffusion D of Al become the highest.

By applying the Al wiring structures shown in FIGS. 4 to 9 to the semiconductor device, even when the heat treatment of about 200° C. or higher is executed in the step after the Al film was formed, the compression stress occurring in the Al film does not reach the critical stress of the occurrence of the peel-off. The peel-off at the interface between the substratum insulating film and the Al film can be prevented. There is also such an effect that the Au element and the Ag element can suppress the acceleration of the grain boundary diffusion of the Al atoms in the Al film. The defect due to the migration can be also prevented. Therefore, the semiconductor device of the high reliability in which the defect such as peel-off or the like does not occur and which operates stably is provided.

### EMBODIMENT 8

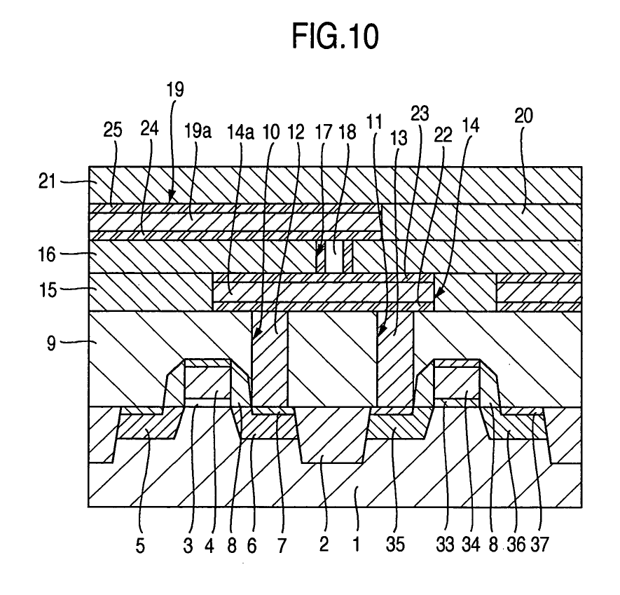

The embodiment 8 of the invention will now be described with reference to FIG. 10. FIG. 10 is a schematic cross sectional view showing a principal portion of a semiconductor device of the embodiment 8. Component elements which are common to those in the embodiment 1 mentioned above are designated by the same reference numerals.

In the embodiment 1, as shown in FIG. 1, each of the wirings 14 of the first layer and the wirings 19 of the second layer has the single-layer structure of the Al film to which Au or Ag has been added. On the other hand, as shown in FIG. 10, the wirings 14 of the first layer and the wirings 19 of the second layer in the embodiment 8 have laminated structures comprising: protecting films 22 and 24; Al films 14a and 19a to which Au or Ag has been added and which are formed on the protecting films 22 and 24; and protecting films 23 and 25 formed on the Al films 14a and 19a. Another structure is similar to that in the embodiment 1 and effects similar to those in the embodiment 1 mentioned above are obtained.

By providing the protecting films, an effect of preventing the Al atoms from being diffused into the silicon substrate in the high temperature heat treatment step is also obtained. By forming the protecting films by, for example, Ti, TiN, Cr, Mo, W, or their alloy, such an effect that the adhesion of the substratum insulating film and the wirings is improved is also obtained. Further, such an effect that the grain boundary diffusion D of Al is suppressed is also obtained. Thus, the semiconductor device of the high reliability in which the peel-off or the defect due to the migration does not occur in the Al wiring structure is obtained.

The semiconductor device of the embodiment 8 is not limited to that mentioned above and the number of wiring layers is not limited to 2, either. This semiconductor device can be also used for a DRAM, an SRAM, an EEPROM, a microcomputer, or the like.

### EMBODIMENT 9

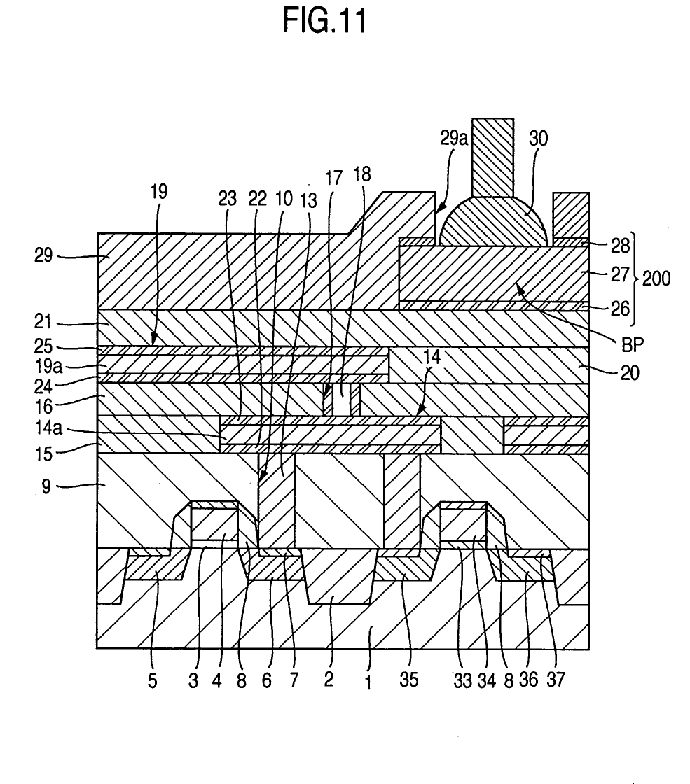

The embodiment 9 of the invention will now be described with reference to FIG. 11. FIG. 11 is a schematic cross sectional view showing a main portion of a semiconductor device according to the embodiment 9. Component elements which are common to those in the embodiment 8 mentioned above are designated by the same reference numerals.

As shown in FIG. 11, the semiconductor device of the embodiment 9 fundamentally has a construction similar to that of the embodiment 8 mentioned above and the following construction is different.

That is, wirings 200 of the top layer are formed on the insulating film 21. Further, an insulating film (final protecting film) 29 is formed on the insulating film 21 so as to cover the wirings 200. The wirings 200 has a bonding pad BP. A bonding opening 29a to expose a wire bonding portion of the bonding pad BP is formed in the insulating film 29.

The wirings 200 has a laminated structure comprising a protecting film 26, an Al film 27 to which Au or Ag has been added and which is formed on the protecting film 26, and a protecting film 28 provided on the Al film 27, while excluding the wire bonding portion of the bonding pad BP. The wire bonding portion of the bonding pad BP has a laminated structure mainly comprising the protecting film 26 and the Al film 27. A bonding wire 30 made of, for example, Au is connected to the wire bonding portion of the bonding pad BP so as to be come into contact with the Al film 27 through the bonding opening 29a.

Another structure is similar to that in the embodiment 8 and effects similar to those in the embodiment 8 mentioned above are obtained. Further, by forming the wirings 200 of the top layer by the Al film to which Au or Ag has been added, even when the bonding wire is connected to the wire bonding portion, the peel-off does not occur at the interface between the wirings of the top layer and the substratum insulating film.

Although the embodiment 9 has been described with respect to the case where the wirings 200 of the top layer has the laminated structure comprising the protecting film 26, the Al film 27 to which Au or Ag has been added, and the protecting film 28, the wirings 200 can be also constructed by a single-layer film of the Al film 27 to which Au or Ag has been added.

The semiconductor device of the embodiment 9 is not limited to that mentioned above and the number of wiring layers is not limited to 3, either. This semiconductor device can be also used for a DRAM, an SRAM, an EEPROM, a microcomputer, or the like.

### EMBODIMENT 10

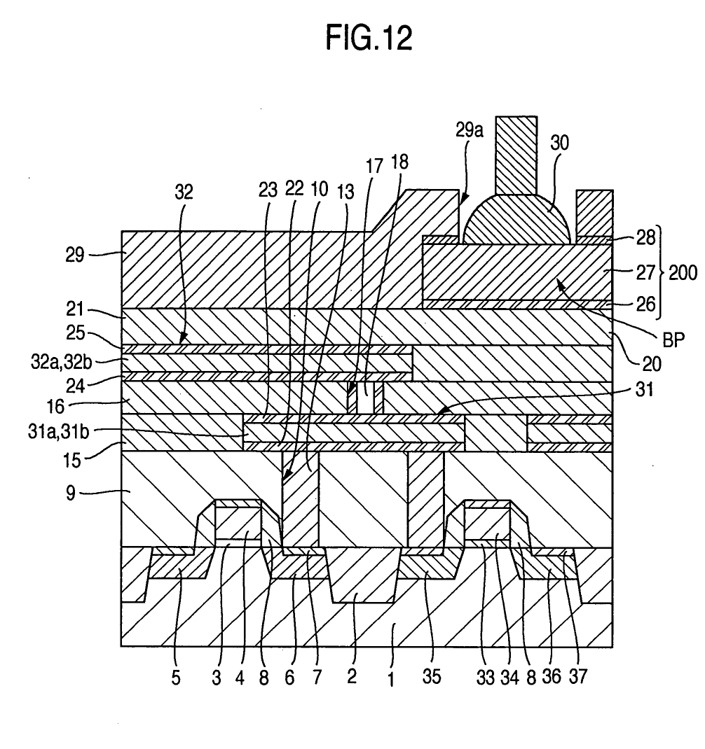

The embodiment 10 of the invention will now be described with reference to FIG. 12. FIG. 12 is a, schematic cross sectional view showing a main portion of a semiconductor device according to the embodiment 10. Component elements which are common to those in the embodiment 9 mentioned above are designated by the same reference numerals.

In the embodiment 9 mentioned above, as shown in FIG. 11, at least either the wirings 14 of the first layer or the wirings 19 of the second layer have the laminated structure including the Al film 14a or 19a to which Au or Ag has been added. On the other hand, in the semiconductor device of the embodiment 10 shown in FIG. 12, wirings 31 of the first layer or wirings 32 of the second layer have the laminated structure including an Al film 31a or 32a containing at least either Cu or Si or a Cu film 31b or 32b. The wirings 200 of the top layer have the laminated structure of the protecting film 26, the Al film 27 to which Au or Ag has been added, and the protecting film 28 in a manner similar to that in FIG. 11.

Another structure is similar to that in the embodiment 9 and effects similar to those in the embodiment 9 mentioned above are obtained. Further, by forming the wirings 200 of the top layer by the Al film to which Au or Ag has been added, even when the bonding wire is connected to the wire bonding portion, the peel-off does not occur at the interface between the wirings of the top layer and the substratum insulating film.

If the wirings other than the wirings 200 of the top layer, that is, the wirings 31 of the first layer and the wirings 32 of the second layer are formed by the Cu wirings, a wiring resistance can be reduced and the semiconductor device which operates at a high speed can be obtained.

If the wirings other than the wirings 200 of the top layer, that is, the wirings 31 of the first layer and the wirings 32 of the second layer are formed by Al alloy films containing at least either Cu or Si, the costs are reduced and the semiconductor device of a reasonable price can be obtained.

By forming the wirings 31 of the first layer by an Al alloy film containing at least either Cu or Si and forming the wirings 32 of the second layer and subsequent layers by Cu films, it is possible to perfectly prevent Cu atoms from being diffused to a region near the silicon substrate. The semiconductor device of the high reliability in which there is no fear of deterioration in characteristics of the device can be obtained.

By forming all of the wirings by the Al films to which Au or Ag has been added, there is such an advantage that the number of targets can be set to 1.

Although the embodiment 10 has been described with respect to the case where the wirings 200 of the top layer have the laminated structure comprising the protecting film 26, the Al film 27 to which Au or Ag has been added, and the protecting film 28, the wirings 200 can be also constructed by the single-layer film of the Al film 27 to which Au or Ag has been added. By forming the protecting films 26 and 28 by, for example, Ti, TiN, Cr, Mo, W, or their alloy, such an effect that the adhesion between the adjacent insulating films 21 and 29 and the Al film 27 is improved is also obtained. Such an effect that the grain boundary diffusion D of Al is suppressed is also obtained. Thus, the semiconductor device of the high reliability in which the peel-off or a defect due to the migration does not occur in the Al wiring structure is obtained. By forming the single-layer film, the number of steps can be reduced and mass-productivity is improved.

Although the embodiment 10 has been shown with respect to the case where the bonding shape is the wire bonding shape, the invention is not limited to such a shape. For example, a bump shape. (stud bump) in which the wire has been cut out can be also used.

The semiconductor device of the embodiment 10 is not limited to that mentioned above and the number of wiring layers is not limited to 3, either. This semiconductor device can be also used for a DRAM, an SRAM, an EEPROM, a microcomputer, or the like.

It should be further understood by those skilled in the art that although the foregoing description has been made on embodiments of the invention, the invention is not limited thereto and various changes and modifications may be made without departing from the spirit of the invention and the scope of the appended claims.

1. A semiconductor device comprising:
a first insulating layer;
a wiring layer which is formed on said first insulating layer, is made of Al, and contains at least either Au or Ag as an additional element; and
a second insulating layer formed on said first insulating layer so as to cover said wiring layer.

2. A device according to claim 1, wherein Au or Ag as said additional element is segregated to a grain boundary in said Al film.

3. A device according to claim 1, wherein a ratio of said Au or said Ag to Al is equal to 0.02 to 2 at %.

4. A device according to claim 1, wherein at least either said first insulating layer or said second insulating layer is an insulating film of a low dielectric constant.

5. A device according to claim 1, wherein at least either said first insulating layer or said second insulating layer is a glass material composed of silicon oxide as a main component material.

6. A semiconductor device comprising:
a semiconductor substrate;
a semiconductor region provided on a principal plane of said semiconductor substrate;
an insulating film provided on the principal plane of said semiconductor substrate;
a contact hole provided in said insulating film; and
an Al film which is provided on said insulating film and electrically connected to said semiconductor region through said contact hole,
wherein said Al film contains at least one kind of additional element of Au or Ag.

7. A device according to claim 6, wherein Au or Ag as said additional element is segregated to a grain boundary in said Al film.

8. A device according to claim 6, wherein a ratio of said Au or said Ag to Al in the Al film is equal to 0.02 to 2 at %.

9. A semiconductor device having a laminated structure in which an insulating layer, a protecting film layer, and a wiring layer made of Al and containing au or Ag as an additional element are laminated in order of a lower layer.

10. A device according to claim 9, wherein Au or Ag as said additional element is segregated to a grain boundary in said Al film.

11. A device according to claim 9, wherein a ratio of said Au or said Ag to Al in the Al film is equal to 0.02 to 2 at %.

12. A device according to claim 9, wherein said insulating layer is an insulating film of a low dielectric constant.

13. A device according to claim 9, wherein said insulating layer is a glass material composed of silicon oxide as a main component material.

14. A device according to claim 9, wherein a main component material of said protecting film layer is one of Ti, TiN, Cr, Mo, and W.

15. A device according to claim 9, wherein a main component material of said protecting film layer is an alloy of one of Ti, TiN, Cr, Mo, and W.

16. A device according to claim 9, wherein a main component material of said protecting film layer is an aluminum oxide.

17. A semiconductor device having a laminated structure in which an insulating layer, a wiring layer made of Al and containing Au or Ag as an additional element, and a protecting film layer are laminated in order of a lower layer.

18. A device according to claim 17, wherein Au or Ag as said additional element is segregated to a grain boundary in said Al film.

19. A device according to claim 17, wherein a ratio of said Au or said Ag to Al in the Al film is equal to 0.02 to 2 at %.

20. A device according to claim 17, wherein said insulating layer is an insulating film of a low dielectric constant.

21. A device according to claim 17, wherein said insulating layer is a glass material composed of silicon oxide as a main component material.

22. A device according to claim 17, wherein a main component material of said protecting film layer is one of Ti, TiN, Cr, Mo, and W.

23. A device according to claim 17, wherein a main component material of said protecting film layer is an alloy of one of Ti, TiN, Cr, Mo, and W.

24. A device according to claim 17, wherein a main component material of said protecting film layer is an aluminum oxide.

25. A semiconductor device having wirings including a bonding pad, wherein
a main component material of said wirings is made of an Al film containing Au or Ag as an additional element.

26. A device according to claim 25, wherein at least an insulating film of a low dielectric constant is formed in a layer lower than said wirings.

27. A device according to claim 25, wherein said wirings have a laminated structure comprising: a first protecting film; said Al film provided on said first protecting film; and a second protecting film provided on said Al film.

28. A device according to claim 27, wherein a main component material of said first and second protecting films is an alloy of one of Ti, TiN, Cr, Mo, and W.
